(19) United States
(12) Patent Application Publication
(10) Pub. No.: US 2008/0122059 A1
(43) Pub. Date: May 29, 2008

(54) STACKED CHIP PACKAGE STRUCTURE AND FABRICATING METHOD THEREOF

(75) Inventors: Che-Ya Chou, Kaohsiung City (TW); Chih-Pin Hung, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/839,290

(22) Filed: Aug. 15, 2007

(30) Foreign Application Priority Data
Nov. 29, 2006 (TW) 95144164

(51) Int. Cl. H01L 23/02

(52) U.S. Cl. 257/686; 257/E23.172

(57) ABSTRACT

A stacked chip package structure including a carrier, a first chip, a second chip, a barrier layer, and a metal piece is provided. The carrier has an upper surface and a corresponding lower surface. The first chip is disposed on the upper surface of the carrier, and electrically connected to the carrier. The second chip is disposed over the first chip, and electrically connected to the carrier. The barrier layer is made of an electrically conductive material, and is disposed between the first chip and the second chip. The metal piece is connected to a border of the barrier layer, and electrically connected to a ground, such that the barrier layer is grounded via the metal piece. A fabricating method of the stacked chip package structure is also provided.

### CROSS-REFERENCE TO RELATED APPLICATION

This application claims the priority benefit of Taiwan application serial no. 95144164, filed on Nov. 29, 2006. All disclosure of the Taiwan application is incorporated herein by reference.

### BACKGROUND OF THE INVENTION

1. Field of the Invention

The present invention relates to a chip package structure and a packaging method thereof. More particularly, the present invention relates to a stacked chip package structure adapted to RF chips and a packaging method thereof.

2. Description of Related Art

With the rapid development of electronics industry, most electronic products are made in the trend of being small, light, and high-speed, among which many electronic products must use RF chips, for example, integrates the RF chips and digital ICs, the RF chips and digital signal processors (DSPs), or the RF chips and baseband (BB) chips, so as to achieve the objective of miniaturization or high speed. However, the RF chips operate at high frequencies, so electromagnetic shielding is required, so as to prevent interference of signals.

FIG. 1 is a schematic cross-sectional view of a conventional stacked chip package structure. Referring to FIG. 1, the stacked chip package structure 100 includes a carrier 110, a first chip 120, a second chip 130, and a metal piece 140. The chip 110 has an upper surface 112 and a lower surface 114. The first chip 120 is disposed on the upper surface 112, and electrically connected to the carrier 110. The second chip 130 is an RF chip disposed over the first chip, and electrically connected to the carrier 110. The metal piece 140 is disposed between the first chip 120 and the second chip 130, and electrically connected to a ground 150, so as to isolate and prevent the RF chip from interfering with signals of the first chip 120. However, the metal piece 140 disposed between the first chip 120 and the second chip 130 increases the entire thickness of the stacked chip package structure 100, which does not meet the requirements on small and light electronic products.

### SUMMARY OF THE INVENTION

Accordingly, the present invention is directed to provide a stacked chip package structure and a fabricating method thereof. In the package structure, a chip (e.g., a baseband chip) and an RF chip are stacked by a chip stacking technique, and a barrier layer made of electrically conductive epoxy resin isolates the RF chip from interfering with signals of the chip. Moreover, the entire thickness of the stacked chip package structure does not increase.

As embodied and broadly described herein, the present invention provides a stacked chip package structure, including a carrier, a first chip, a second chip, a barrier layer, and a metal piece. The carrier has an upper surface and a corresponding lower surface. The first chip is disposed on the upper surface of the carrier, and electrically connected to the carrier. The second chip is disposed over the first chip, and electrically connected to the carrier. The barrier layer is made of an electrically conductive material, and is disposed between the first chip and the second chip. The metal piece is connected to a border of the barrier layer, and electrically connected to a ground, such that the barrier layer is grounded via the metal piece.

In an embodiment of the present invention, the carrier includes a plurality of solder balls disposed on the lower surface.

In an embodiment of the present invention, the first chip includes a digital integrated circuit, a digital signal processor, or a baseband chip.

In an embodiment of the present invention, the first chip is electrically connected to the carrier by means of flip chip bonding or wire bonding.

In an embodiment of the present invention, the second chip includes an RF chip.

In an embodiment of the present invention, the second chip is electrically connected to the carrier by means of wire bonding.

In an embodiment of the present invention, the barrier layer is made of electrically conductive epoxy resin.

In an embodiment of the present invention, the ground is located on the carrier.

In an embodiment of the present invention, the metal piece is electrically connected to the ground via a bonding wire.

In an embodiment of the present invention, the stacked chip package structure further includes a molding compound disposed on the carrier and covering the first chip, the second chip, the barrier layer, and the metal piece.

The present invention further provides a fabricating method of a stacked chip package structure, which includes the following steps. First, a circuit substrate having an upper surface and a corresponding lower surface is provided. Then, a first chip is disposed on the upper surface of the circuit substrate. Next, the first chip is electrically connected to the circuit substrate. Afterwards, a metal piece having an opening is disposed on the first chip. Then, an electrically conductive material is disposed in the opening of the metal piece, and covers the first chip. The electrically conductive material is electrically connected to the metal piece. Then, a second chip is disposed over the metal piece and the electrically conductive material. Finally, the second chip is electrically connected to the circuit substrate.

In an embodiment of the present invention, the method further includes providing an adhesive material on the upper surface of the circuit substrate before disposing the first chip.

In an embodiment of the present invention, the method further includes heating the adhesive material after disposing the first chip, so as to adhere the first chip onto the circuit substrate.

In an embodiment of the present invention, the method further includes heating the adhesive material and the electrically conductive material after disposing the second chip, so as to adhere the first chip and the second chip at the same time.

In the stacked chip package structure of the present invention, the RF chip and another chip (e.g., a baseband chip) are stacked together by the chip stacking technique. The barrier layer made of electrically conductive epoxy resin can effectively isolate the RF chip from interference resulting from the signals of the chip below the RF chip without increasing the overall thickness of the stacked chip package structure.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional stacked chip package structure.

FIG. 2 is a cross-sectional view of a stacked chip package structure according to an embodiment of the present invention.

FIG. 3 is a cross-sectional view of a stacked chip package structure according to another embodiment of the present invention.

FIGS. 4A-4H are schematic views illustrating processes of the fabricating method of the stacked chip package structure of FIG. 2.

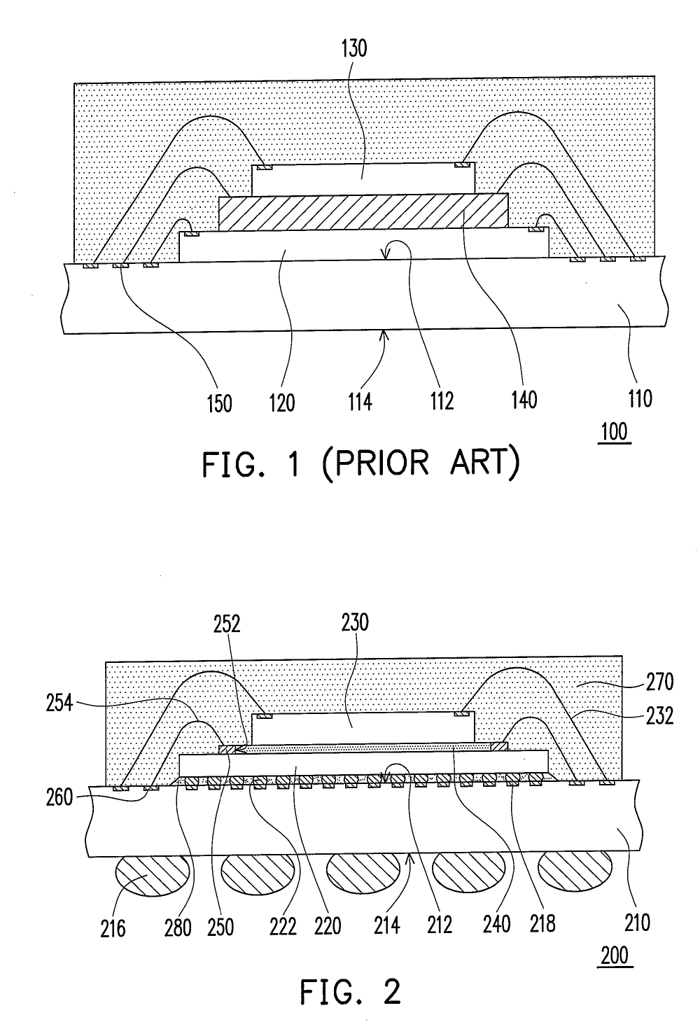

### DESCRIPTION OF EMBODIMENTS

FIG. 2 is a schematic cross-sectional view of a stacked chip package structure according to an embodiment of the present invention. Referring to FIG. 2, the stacked chip package structure 200 is adapted to a stacked chip package structure with RF chips, so as to reduce the interference to the RF chips.

The stacked chip package structure 200 includes a carrier 210, a first chip 220, a second chip 230, a barrier layer 240, and a metal piece 250. The carrier 210 has an upper surface 212 and a corresponding lower surface 214, and may be a printed circuit board (PCB), a circuit substrate, a chip carrier, or the like. In addition, a plurality of solder balls 216 may be optionally disposed on the lower surface 214 of the carrier 210, such that the stacked chip package structure 200 may be electrically connected to other elements via the solder balls 216.

The first chip 220 is disposed on the upper surface 212 of the carrier 210, and is electrically connected to the carrier 210. The first chip 220 may be a digital integrated circuit, a digital signal processor, a baseband chip, or the like. In this embodiment, the first chip 220 is electrically connected to the carrier 210 by means of flip chip bonding. Further, the first chip 220 has a plurality of bumps 222 on a surface facing the carrier 210, such that the first chip 220 may be electrically connected to the carrier 210 via the bumps 222. In addition, the first chip 220 may also be electrically connected to the carrier 210 in other ways. For example, the first chip 220 may be electrically connected to the carrier 210 by means of wire bonding. The method of electrically connecting the first chip 220 to the carrier 210 is not limited in the present invention.

The second chip 230 is disposed over the first chip 210, and electrically connected to the carrier 210. The second chip 230 is, for example, an RF chip. In this embodiment, the second chip 230 is electrically connected to the carrier 210 by means of wire bonding. In more detail, the second chip 230 may be connected to signal contacts 218 on the carrier 210 via a bonding wire 232.

The barrier layer 240 is made of an electrically conductive material, and is disposed between the first chip 220 and the second chip 230. In this embodiment, the barrier layer 240 may be an adhesive material, for example, electrically conductive epoxy resin, thermally curable epoxy resin, or photo curable epoxy resin, for fixing the second chip 230 onto the first chip 220.

The metal piece 250 is connected to the border of the barrier layer 240, and is connected to a ground 260 on the carrier 210 via a bonding wire 254, such that the barrier layer 240 is grounded via the metal piece 250. In this embodiment, the metal piece 250 is an annular metal piece surrounding the border of the barrier layer 240. However, the metal piece 250 may also be a bar-shaped metal piece connected to a part of the border of the barrier layer 240, so that the barrier layer 240 may be grounded via the bar-shaped metal piece. The shape of the metal piece 250 is not limited in the present invention.

Moreover, the stacked chip package structure 200 may further include a molding compound 240 covering the first chip 220, the second chip 230, the barrier layer 240, and the metal piece 250, so as to protect the elements on the carrier 210 from damages and moisture.

As the RF chip is sensitive to noise, the barrier layer 240 is disposed between the RF chip and the first chip 220 to effectively isolate the RF chip from interference resulting from the signals of the first chip 220 in this embodiment. The barrier layer 240 is an adhesive material for fixing the second chip 230 onto the first chip 220, so the existence of barrier layer 240 will not increase the overall thickness of the stacked chip package structure 200.

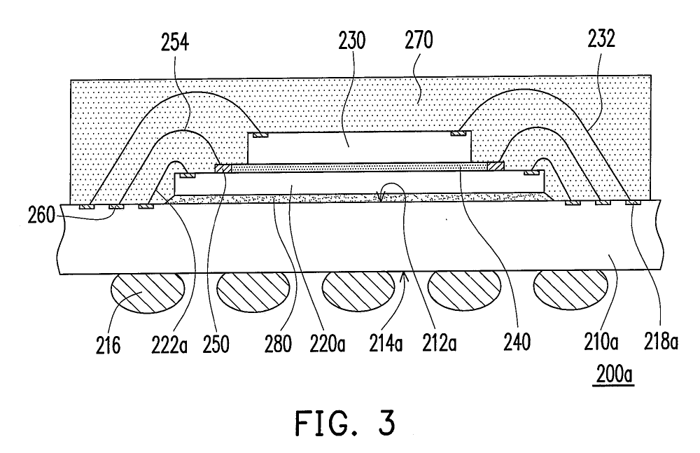

FIG. 3 is a schematic cross-sectional view of a stacked chip package structure according to another embodiment of the present invention. Referring to FIG. 3, the stacked chip package structure 200a is substantially similar to the stacked chip package structure 200 of FIG. 2, while the difference is that in the stacked chip package structure 200a of FIG. 3, the first chip 220a is electrically connected to the carrier 210a via a bonding wire 222a.

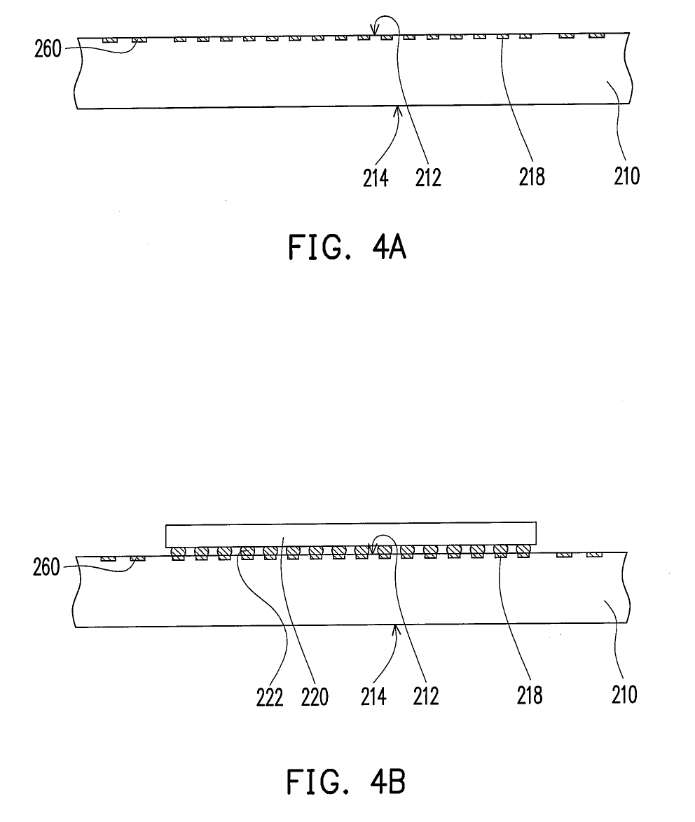

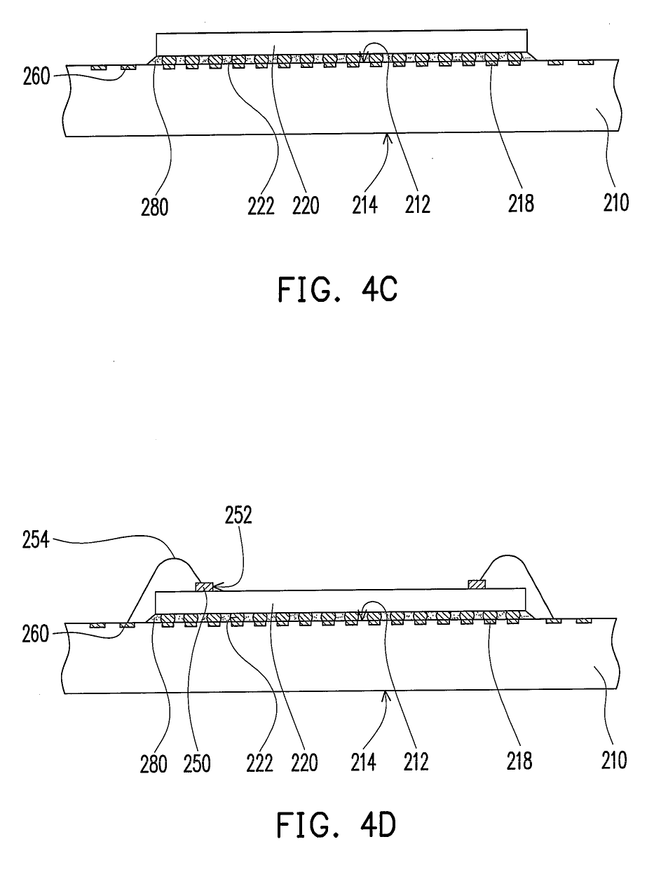

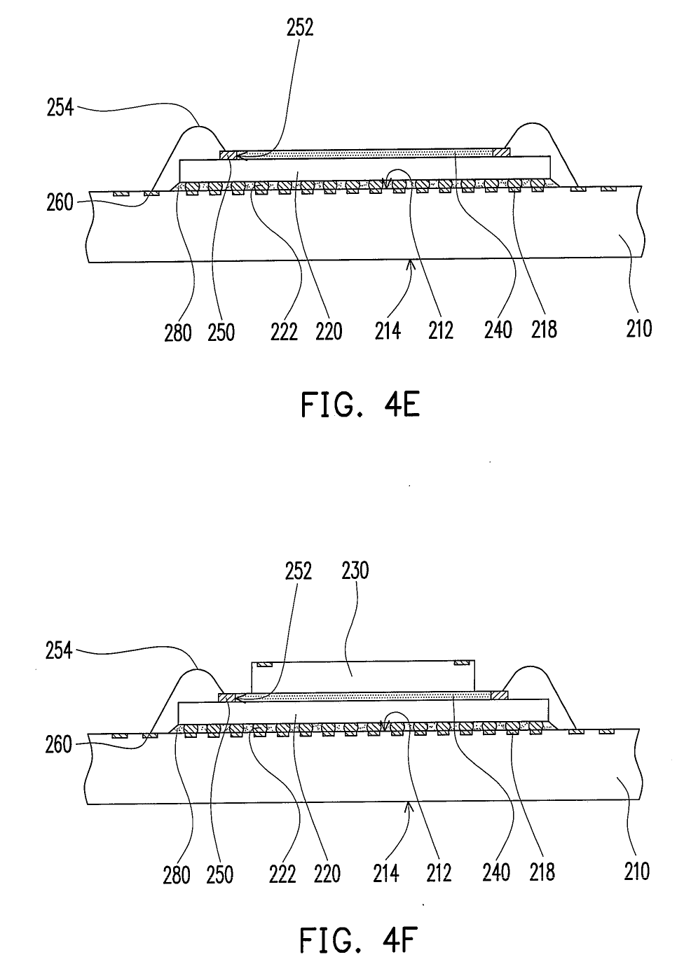

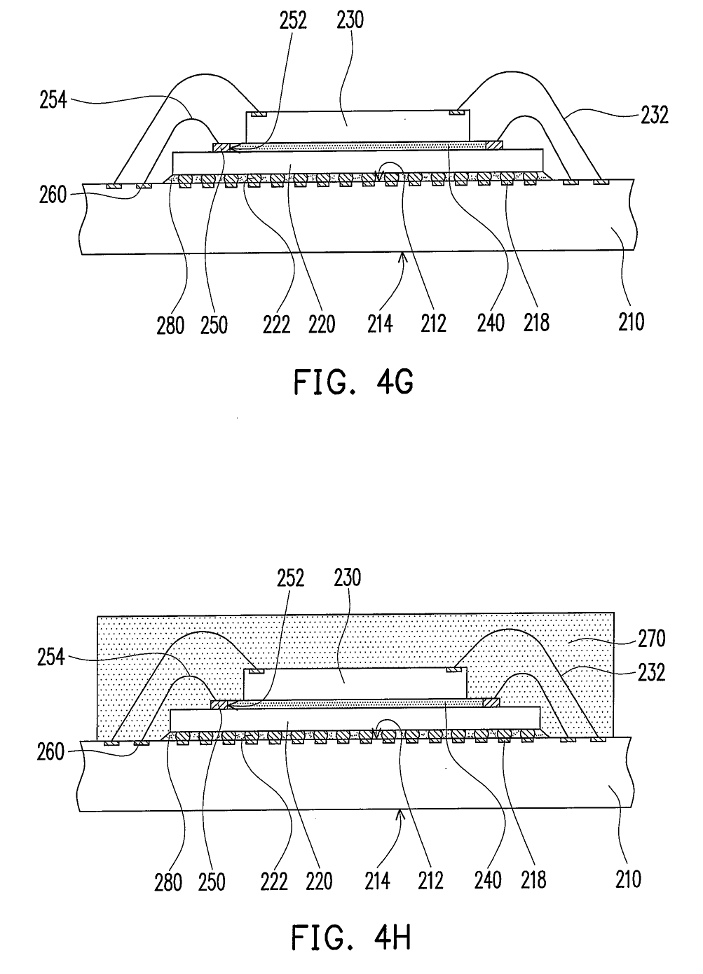

Then, a fabricating method of the stacked chip package structure is described with reference to the accompanying drawings as follows. FIGS. 4A-4H are schematic views illustrating processes of the fabricating method of the stacked chip package structure of FIG. 2. Referring to FIGS. 4A-4H, the fabricating method of the stacked chip package structure 200 includes the following steps. First, as shown in FIG. 4A, a circuit substrate (i.e., the carrier) 210 having an upper surface 212 and a corresponding lower surface 214 is provided.

Then, as shown in FIG. 4B, the first chip 220 is disposed on the upper surface 212 of the circuit substrate 210. Then, the first chip 220 is electrically connected to the circuit substrate 210. The method of electrically connecting the first chip 220 to the circuit substrate 210 is, for example, heating to melt the bumps 222, such that the first chip 220 is electrically connected to the circuit substrate 210 via the bumps 222.

After the first chip 220 is electrically connected to the circuit substrate 210, referring to FIG. 4, an adhesive material 280 (e.g., an underfill) may be filled between the first chip 220 and the circuit substrate 210, so as to improve the reliability of the connection between the first chip 220 and the circuit substrate 210.

After that, as shown in FIG. 4D, a metal piece 250 having an opening 252 is disposed on the first chip 220. The metal piece 250 may be electrically connected to the ground 260 via the bonding wire 254.

Then, as shown in FIG. 4E, an electrically conductive material (i.e., the barrier layer) 240 is disposed in the opening 252 and covering the first chip 220, such that the electrically conductive material 240 is electrically connected to the metal piece 250. The electrically conductive material 240 may be an adhesive, for example, electrically conductive epoxy resin, photo curable epoxy resin, or thermally curable epoxy resin, for fixing the second chip 230 onto the first chip 220.

Then, as shown in FIG. 4F, the second chip 230 is disposed above the metal piece 250 and the electrically conductive material 240. Then, the electrically conductive material 240 is thermally cured or UV cured, such that the first chip 220 and the second chip 230 are cured. In addition, the step of curing the adhesive material 280 may be performed together with the curing of the electrically conductive material 240.

Next, as shown in FIG. 4G, the second chip 230 is electrically connected to the circuit substrate 210. In this embodiment, the second chip 230 is electrically connected to the signal contacts 218 on the circuit substrate 210 via the bonding wire 232. Thus, the basic processes of fabricating the stacked chip package structure are completed.

In addition, referring to FIG. 4H, after electrically connecting the second chip 230 to the circuit substrate 210, a molding compound 270 is optionally formed on the carrier 210. The molding compound 270 covers the first chip 220, the second chip 230, the barrier layer 240, and the metal piece 250, so as to protect the elements on the carrier 210 from damages and moisture.

Then, referring to FIG. 2, a plurality of solder balls 216 may be optionally disposed on the lower surface 214 of the circuit substrate 210, such that the stacked chip package structure 200 is electrically connected to other elements via the solder balls 216.

In this embodiment, the first chip 220 is electrically connected to the circuit substrate 210 by means of flip chip bonding. However, the first chip 220 may also be electrically connected to the circuit substrate 210 in other ways, such as wire bonding. When the first chip 220 and the circuit substrate 210 are electrically connected by means of wire bonding, an adhesive material may be added onto the circuit substrate 210 first, and the adhesive material may be thermally curable epoxy resin or photo curable epoxy resin. After that, the first chip 220 is disposed on the adhesive material, and the adhesive material is cured. Then, the first chip 220 is connected to the signal contacts 218 on the circuit substrate 210 by means of wire bonding.

To sum up, in the stacked chip package structure of the present invention, the RF chip and another chip (e.g., the baseband chip) are stacked by the chip stacking technique. A barrier layer made of an electrically conductive epoxy resin is disposed between the two chips. The barrier layer is grounded via a metal piece, and the metal piece is connected to a border of the barrier layer, so as to effectively isolate the RF chip from interference resulting from the signals of other chips below the RF chip. As the barrier layer is the adhesive material for fixing the chips, the existence of the barrier layer does not increase the overall thickness of the stacked chip package structure.

It will be apparent to persons of ordinary art in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A stacked chip package structure, comprising:
a carrier, having an upper surface and a corresponding lower surface;
a first chip, disposed on the upper surface of the carrier, and electrically connected to the carrier;
a second chip, disposed over the first chip, and electrically connected to the carrier;
a barrier layer, made of an electrically conductive material, and disposed between the first chip and the second chip; and
a metal piece, connected to a border of the barrier layer, and electrically connected to a ground, so that the barrier layer is grounded via the metal piece.

2. The stacked chip package structure as claimed in claim 1, wherein the substrate comprises a plurality of solder balls disposed on the lower surface.

3. The stacked chip package structure as claimed in claim 1, wherein the first chip comprises a digital integrated circuit, a digital data processor, or a baseband chip.

4. The stacked chip package structure as claimed in claim 1, wherein the first chip is electrically connected to the carrier by means of flip chip bonding or wire bonding.

5. The stacked chip package structure as claimed in claim 1, wherein the second chip comprises an RF chip.

6. The stacked chip package structure as claimed in claim 1, wherein the second chip is electrically connected to the carrier by means of wire bonding.

7. The stacked chip package structure as claimed in claim 1, wherein the barrier layer is made of electrically conductive epoxy resin.

8. The stacked chip package structure as claimed in claim 1, wherein the ground is located on the carrier.

9. The stacked chip package structure as claimed in claim 8, wherein the metal piece is electrically connected to the ground via a bonding wire.

10. The stacked chip package structure as claimed in claim 1, further comprising a molding compound disposed on the carrier and covering the first chip, the second chip, the barrier layer, and the metal piece.
